(19) United States
(12) Patent Application Publication
(10) Pub. No.: US 2025/0062060 A1
(43) Pub. Date: Feb. 20, 2025

(54) Spin-Orbit Torque Material and Device, and Use of Delafossite Oxide Thin Film

(71) Applicant: Tsinghua University, Beijing (CN)

(72) Inventors: Tianxiang NAN, Beijing (CN); Yuejie ZHANG, Beijing (CN)

(21) Appl. No.: 18/422,057

(22) Filed: Jan. 25, 2024

(30) Foreign Application Priority Data
Aug. 15, 2023 (CN) 202311023012.1

(51) Int. Cl. H01F 10/12; G11C 11/16; H01F 10/32; H10N 50/10

(52) U.S. Cl. CPC H01F 10/123; H01F 10/329; H10N 50/10; G11C 11/161

(57) ABSTRACT

Disclosed are a spin-orbit torque material and device, and use of a delafossite oxide thin film, which relate to the field of spintronics. A chemical formula of the spin-orbit torque material is ABO₂; wherein A and B are different heavy metal atoms, O is an oxygen atom, and a ratio between the numbers of A, B, and O atoms is 1:1:2. The spin-orbit torque material of an embodiment of the present application has higher spin-orbit torque efficiency and lower resistivity, and can reduce the power consumption of a spin-orbit torque device when it is used in the device.

### CROSS-REFERENCE TO RELATED APPLICATION

This application claims the priority to Chinese Patent Application No. 202311023012.1 filed on Aug. 15, 2023, which is hereby incorporated herein by reference in its entirety.

### TECHNICAL FIELD

Embodiments of the present application relate to the field of spintronics, in particular to a spin-orbit torque material, a spin-orbit torque device, and use of a delafossite oxide thin film.

### BACKGROUND

A spin-orbit torque (SOT) device is a semiconductor device prepared based on spin-orbit torque effect. Its working mode is that a spin current will be generated after the charge passes through a spin-orbit torque material, and the spin current will further control the magnetic moment of a magnetic layer. However, large-scale applications of spin-orbit torque devices have not yet been realized at present, and the main factors include the following two aspects.

(1) It requires a certain current density to drive magnetic moment reversal, but the efficiency of the spin-orbit torque generated by the current spin-orbit torque material is relatively low, which leads to inability to drive the magnetic moment reversal.

(2) The resistivity of the current spin-orbit torque material is relatively high.

The power consumption relationship formula of the spin-orbit torque device is:

$${P}_{write} ∝ {[ ( 1 + s ) / {θ}_{SH} ]}^{2} {ρ}_{xx} .$$

In this formula, P_{write} represents write power consumption of the device; θ_{SH} represents spin-orbit torque efficiency, and ρₓₓ represents resistivity.

It can be seen that the write power consumption of the device is inversely proportional to the spin-orbit torque efficiency, and directly proportional to the resistivity.

Low spin-orbit torque efficiency and high resistivity will lead to higher write power consumption of the spin-orbit torque device, which further restricts the wide application of the spin-orbit torque device to a greater extent.

### SUMMARY

The following is a summary of the subject matter described in detail herein. This summary is not intended to limit the scope of protection of this application.

The embodiments of the present application provide a spin-orbit torque material, a spin-orbit torque device, and use of a delafossite oxide thin film. The spin-orbit torque material according to an embodiment of the present application has higher spin-orbit torque efficiency and lower resistivity, and can reduce the power consumption of a spin-orbit torque device when it is used in the device.

An embodiment of the present application provides a spin-orbit torque material, the spin-orbit torque material has a spin-orbit torque effect, and a chemical formula of the spin-orbit torque material is ABO₂; wherein A and B are different heavy metal atoms, O is an oxygen atom, and a ratio between the numbers of A, B, and O atoms is 1:1:2.

In an embodiment of the present application, the A and B may each independently be any one of platinum, palladium, cobalt, chromium, tantalum, tungsten, copper, hafnium, rhenium, iridium, gold, silver, and titanium.

In an embodiment of the present application, the A may be any one of platinum and palladium, and the B may be any one of cobalt and chromium.

In an embodiment of the present application, the spin-orbit torque material may be an ABO₂ thin film which may include a single-layered or multi-layered ABO₂ atomic layer; wherein each ABO₂ atomic layer includes an A atomic layer and a BO₂ atomic layer, and the multi-layered ABO₂ atomic layer is formed by A atomic layers and BO₂ atomic layers which are stacked alternately.

In an embodiment of the present application, the ABO₂ thin film may be a single crystal thin film or an amorphous thin film.

In an embodiment of the present application, the thickness of the ABO₂ thin film may be 8 nm to 150 nm.

An embodiment of the present application also provides a spin-orbit torque device, the spin-orbit torque device may include at least one spin-orbit torque material as provided above in an embodiment of the present application.

In an embodiment of the present application, the spin-orbit torque device may include a spin-orbit torque generating layer which includes the spin-orbit torque material.

In an embodiment of the present application, the spin-orbit torque device may be a storage device, a logic device, or a sensor device.

In an embodiment of the present application, the spin-orbit torque generating layer may be configured to drive magnetization reversal, perturb magnetic moment, or excite magnetic resonance.

An embodiment of the present application also provides use of a delafossite oxide thin film for providing a spin-orbit torque effect, wherein a chemical formula of the delafossite oxide is ABO₂; and wherein A and B are different heavy metal atoms, O is an oxygen atom, and a ratio between the numbers of A, B, and O atoms is 1:1:2.

In an embodiment of the present application, the A and B may each independently be any one of platinum, palladium, cobalt, chromium, tantalum, tungsten, copper, hafnium, rhenium, iridium, gold, silver, and titanium.

In an embodiment of the present application, the A may be any one of platinum and palladium, and the B may be any one of cobalt and chromium.

In an embodiment of the present application, the delafossite oxide thin film may include a single-layered or multi-layered ABO₂ atomic layer, wherein each ABO₂ atomic layer includes an A atomic layer and a BO₂ atomic layer, and the multi-layered ABO₂ atomic layer is formed by A atomic layers and BO₂ atomic layers which are stacked alternately.

In an embodiment of the present application, the use may include the employment of the delafossite oxide thin film in a spin-orbit torque storage device, a spin-orbit torque logic device, or a spin-orbit torque sensor device to provide a spin-orbit torque effect, and the utilization of the spin-orbit torque effect to drive magnetization reversal, perturb magnetic moment, or excite magnetic resonance.

The spin-orbit torque material of an embodiment of the present application may have both higher spin-orbit torque efficiency and lower resistivity. For example, the spin-orbit torque efficiency may be higher than 0.1 (for example, the spin-orbit torque efficiency is higher than 0.5), and the resistivity is less than or equal to 20 μΩcm. Therefore, the spin-orbit torque material may reduce the magnetization reversal power consumption of a spin-orbit torque device when it is used in the device, i.e., the spin-orbit torque material of an embodiment of the present application is of practical and important value in reducing the write power consumption of the spin-orbit torque device.

Additional features and advantages of the present application will be set forth in the description which follows, and in part will become apparent from the description, or may be learned by practice of the present application. Other advantages of the present application may be realized and obtained by solutions described in the description and the drawings.

### BRIEF DESCRIPTION OF THE DRAWINGS

The accompanying drawings are used to provide an understanding of the technical solutions of the present application, and constitute a part of the specification. They are used to explain the technical solutions of the present application together with the embodiments of the present application, and do not constitute a limitation to the technical solutions of the present application.

FIG. 1 is a schematic diagram of atomic structure of a single-layered ABO₂ atomic layer.

FIG. 2 is a schematic diagram of atomic structure of a multi-layered ABO₂ atomic layer.

FIG. 3 is scanning transmission electron microscopy diagram of a single crystal epitaxial PtCoO₂ thin film.

FIG. 4 is a curve of resistivity of a PtCoO₂ thin film as a function of thickness.

FIG. 5 is a diagram of spin-orbit torque efficiency-resistivity comparison between a single crystal epitaxial PtCoO₂ thin film and other materials.

FIG. 6 is a curve of Hall resistance as a function of current density in a perpendicular magnetization reversal mode.

### DETAILED DESCRIPTION

In order to make the object, technical solutions and advantages of the present application clearer, the embodiments of the present application will be described below in detail with reference to the accompanying drawings. It should be noted that the following embodiments of the present application and the features of the embodiments may be arbitrarily combined with each other provided that there is no conflict.

Embodiments of the present application are not necessarily limited to the dimensions shown in the drawings, and the shapes and sizes of the components in the drawings do not reflect true proportions. In addition, the drawings schematically show ideal examples, and embodiments of the present application are not limited to the shapes or values shown in the drawings.

In the description of the present application, “film (or thin film)” and “layer” may be interchanged with each other. For example, “spin-orbit torque generating layer” may sometimes be changed to “spin-orbit torque generating film (or thin film)”. Likewise, “delafossite oxide thin film” may sometimes be changed to “delafossite oxide Layer”.

At present, methods employed to reduce write power consumption of a spin-orbit torque device mainly includes the following methods (1) and (2).

### (1) Regulating Anisotropic Strength of the Magnetic Layer.

For example, it is feasible to reduce the magnetic anisotropic properties of the ferromagnetic layer by means of externally applying a voltage or stress, and the like without increasing the write current density, and realize the control of the magnetic layer at a low current density (i.e., data writing).

Although the magnetic anisotropic strength of the ferromagnetic layer may be reduced by externally applying a voltage or stress, a voltage regulator or a stress regulator needs to be additionally introduced. The introduction of the voltage regulator or stress regulator not only occupies a certain space, which restricts the improvement of integration density of the spin-orbit torque device, but also increases the processing cost of the device, which reduces the commercial advantage of the spin-orbit torque device in terms of cost.

### (2) Increasing Spin-Orbit Torque Efficiency.

In order to improve the spin-orbit torque efficiency, the current main research methods include: 1) improving the interface between the spin-orbit torque layer and the ferromagnetic layer; and 2) adjusting the film layer structure of the spin-orbit layer and doping the spin-orbit layer.

Regulation of the interface effect between the spin-orbit torque layer and the ferromagnetic layer may reduce the scattering effect of spin current at the interface and improve the utilization efficiency of the spin current generated by the spin-orbit torque material, but it still cannot greatly improve the spin-orbit torque efficiency in fundamental. The current known methods of adjusting the film layer structure of the spin-orbit layer and doping the spin-orbit layer improve the spin-orbit torque efficiency of some spin-orbit torque materials, but at the same time increase the resistivity of the device, resulting in high power consumption.

An embodiment of the present application provides a spin-orbit torque material, the spin-orbit torque material has a spin-orbit torque effect, and a chemical formula of the spin-orbit torque material is ABO₂; wherein A and B are different heavy metal atoms, O is an oxygen atom, and a ratio between the numbers of A, B, and O atoms is 1:1:2.

In an embodiment of the present application, the A and B may each independently be any one of platinum (Pt), palladium (Pd), cobalt (Co), chromium (Cr), tantalum (Ta), tungsten (W), copper (Cu), hafnium (Hf), rhenium (Rc), iridium (Ir), gold (Au), silver (Ag), and titanium (Ti).

In an embodiment of the present application, the A may be any one of platinum and palladium, and the B may be any one of cobalt and chromium.

In an embodiment of the present application, the spin-orbit torque material may be PtCoO₂, PdCoO₂, or PdCrO₂.

In an embodiment of the present application, the spin-orbit torque material may be an ABO₂ thin film.

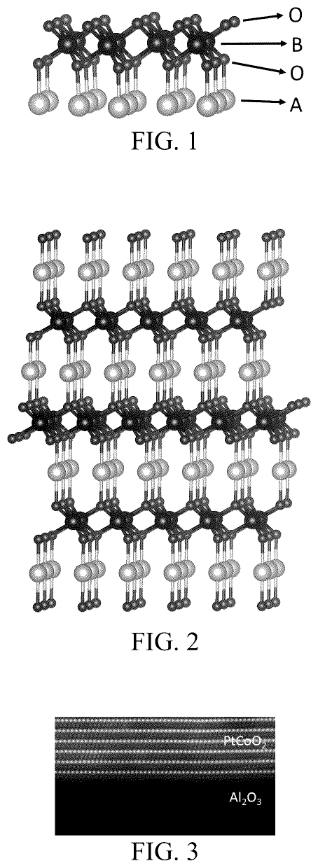

FIG. 1 and FIG. 2 are schematic diagrams of atomic structure of a single-layered ABO₂ atomic layer and a multi-layered ABO₂ atomic layer, respectively.

As shown in FIG. 1 and FIG. 2, the ABO₂ thin film may include a single-layered or multi-layered ABO₂ atomic layer, wherein each ABO₂ atomic layer includes an A atomic layer and a BO₂ atomic layer, and the multi-layered ABO₂ atomic layer is formed by A atomic layers and BO₂ atomic layers which are stacked alternately.

In an embodiment of the present application, the ABO₂ thin film may be a single crystal thin film, as shown in FIG. 3. In another embodiment, the ABO₂ thin film may also be an amorphous thin film.

In an embodiment of the present application, the thickness of the ABO₂ thin film may be 8 nm to 150 nm.

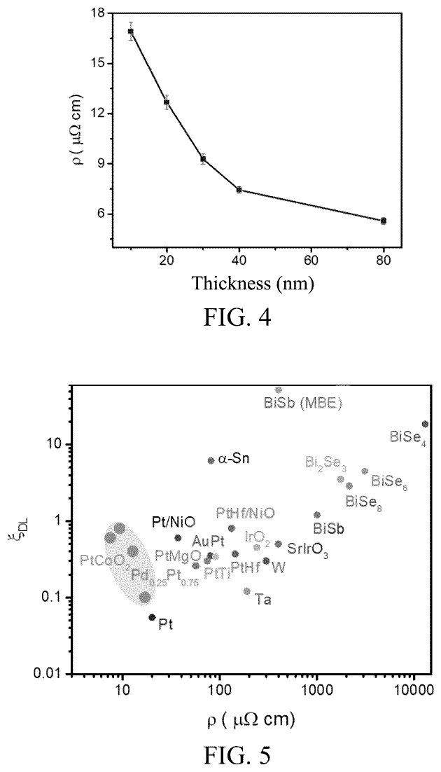

FIG. 4 is a curve of resistivity of a PtCoO₂ thin film as a function of thickness. As shown in FIG. 4, when the thickness of the PtCoO₂ thin film varies from 10 nm to 80 nm, the resistivity of the PtCoO₂ thin film is not more than 18 μΩcm.

In an embodiment of the present application, the resistivity of the spin-orbit torque material is less than or equal to 20 μΩcm.

In an embodiment of the present application, the spin-orbit torque material has a spin-orbit torque efficiency higher than 0.1.

FIG. 5 is a diagram of spin-orbit torque efficiency-resistivity comparison between a single crystal epitaxial PtCoO₂ thin film and other materials.

As shown in FIG. 5, other material systems, such as topological insulator materials, topological semi-metallic materials, and alloys, etc., may have higher spin-orbit torque efficiency, but at the same time have higher resistivity. The single crystal epitaxial PtCoO₂ thin film selected in an embodiment of the present application may maintain higher spin-orbit torque efficiency, while having a low resistivity.

Therefore, the spin-orbit torque material of an embodiment of the present application may have both higher spin-orbit torque efficiency and lower resistivity, for example, the spin-orbit torque efficiency may be higher than 0.1, and the resistivity is less than or equal to 20 μΩcm.

An embodiment of the present application also provides a spin-orbit torque device, the spin-orbit torque device may include at least one spin-orbit torque material as provided above in an embodiment of the present application.

Since the spin-orbit torque material of an embodiment of the present application may have both higher spin-orbit torque efficiency and lower resistivity, the spin-orbit torque material may reduce the magnetization reversal power consumption of a spin-orbit torque device when it is used in the device, i.e., the spin-orbit torque material of an embodiment of the present application is of practical and important value in reducing the write power consumption of the spin-orbit torque device.

In an embodiment of the present application, the spin-orbit torque device may include a spin-orbit torque generating layer which includes the spin-orbit torque material.

For example, the spin-orbit torque generating layer may include at least one spin-orbit torque material. When the spin-orbit torque generating layer includes multiple spin-orbit torque materials, each spin-orbit torque material may be made into a thin film separately, and then the thin films of the multiple spin-orbit torque materials are stacked together to form the spin-orbit torque generating layer.

In an embodiment of the present application, the spin-orbit torque device may be a storage device, a logic device, or a sensor device. For example, the spin-orbit torque device may be a spin-orbit torque magnetic random access memory (SOT-MRAM).

In an embodiment of the present application, the spin-orbit torque generating layer may be configured to drive magnetization reversal, perturb magnetic moment, or excite magnetic resonance.

In an embodiment of the present application, the driving magnetization reversal includes, but is not limited to, magnetization reversal of a magnetic material, wherein the magnetic material includes a ferromagnetic material, a ferrimagnetic material; and includes not only a zero-dimensional magnetic material, but also a one-dimensional magnetic material, and a two-dimensional magnetic material.

When the spin-orbit torque device is used as a storage device, it is mainly based on magnetic moment reversal, but for applications such as a sensor device, it is not necessary to reverse the magnetic moment, and it is only needed to perturb magnetic moment or excite resonance and other characteristics in order to realize the use conditions. Therefore, the spin-orbit torque generating layer is not limited to devices that need magnetization reversal, but can also be applied to devices that do not need magnetization reversal.

In an embodiment of the present application, an in-plane magnetization film may be prepared on the spin-orbit torque generating layer, thereby realizing magnetization reversal in a pure electrical mode; alternatively, a perpendicular magnetization film may be prepared on the spin-orbit torque generating layer, thereby realizing perpendicular magnetization reversal in an electrical mode assisted by a magnetic field.

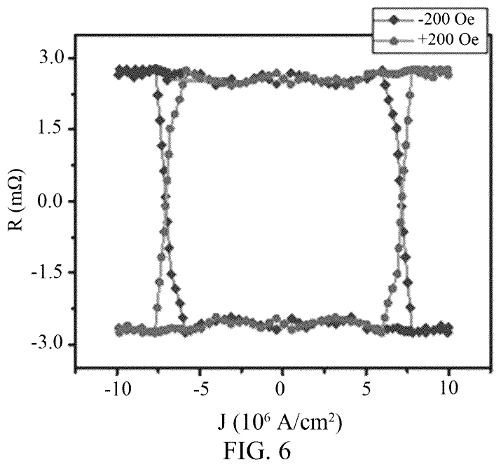

PtCoO₂ is used as a spin-orbit torque generating layer, a perpendicular magnetization film is prepared thereon, and the perpendicular magnetization reversal efficiency is investigated to obtain the curve of Hall resistance (R) as a function of current density (J) in the perpendicular magnetization reversal mode as shown in FIG. 6. As can be seen from FIG. 6, magnetic moment may be reversed using current, and the current density is less than 7×10⁻⁶ A/cm², indicating that the efficiency of the spin-orbit torque of PtCoO₂ as the spin-orbit torque generating layer is relative high.

An embodiment of the present application also provides use of a delafossite oxide thin film for providing a spin-orbit torque effect, a chemical formula of the delafossite oxide is ABO₂; wherein A and B are different heavy metal atoms, O is an oxygen atom, and a ratio between the numbers of A, B, and O atoms is 1:1:2.

In an embodiment of the present application, the A and B may each independently be any one of platinum, palladium, cobalt, chromium, tantalum, tungsten, copper, hafnium, rhenium, iridium, gold, silver, and titanium.

In an embodiment of the present application, the A may be any one of platinum and palladium, and the B may be any one of cobalt and chromium.

In an embodiment of the present application, the delafossite oxide thin film may include a single-layered or multi-layered ABO₂ atomic layer, wherein each ABO₂ atomic layer includes an A atomic layer and a BO₂ atomic layer, and the multi-layered ABO₂ atomic layer is formed by A atomic layers and BO₂ atomic layers which are stacked alternately.

In an embodiment of the present application, the delafossite oxide thin film may be a single crystal thin film or an amorphous thin film.

In an embodiment of the present application, the thickness of the delafossite oxide thin film may be from 8 nm to 150 nm.

In an embodiment of the present application, the use may include the employment of the delafossite oxide thin film in a spin-orbit torque storage device, a spin-orbit torque logic device, or a spin-orbit torque sensor device to provide a spin-orbit torque effect, and the utilization of the spin-orbit torque effect to drive magnetization reversal, perturb magnetic moment, or excite magnetic resonance.

In an embodiment of the present application, the ABO₂ thin film or the delafossite oxide thin film may be prepared with reference to the method disclosed in the literature Solution-processable epitaxial metallic delafossite oxide films. Advanced Functional Materials, 2020, 2002375.

Although the embodiments disclosed in the present application are as above, the contents described are only the embodiments adopted for the convenience of understanding the present application, and are not used to limit the present application. Any person skilled in the field to which this application belongs may make any modifications and changes in the form and details of implementation without departing from the spirit and scope disclosed in this application, but the scope of patent protection of this application shall still be subject to the scope defined in the appended claims.

1. A spin-orbit torque material, having a spin-orbit torque effect, wherein a chemical formula of the spin-orbit torque material is ABO₂; and
wherein A and B are different heavy metal atoms, O is an oxygen atom, and a ratio between the numbers of A, B, and O atoms is 1:1:2.

2. The spin-orbit torque material according to claim 1, wherein the A and B are each independently any one of platinum, palladium, cobalt, chromium, tantalum, tungsten, copper, hafnium, rhenium, iridium, gold, silver, and titanium.

3. The spin-orbit torque material according to claim 2, wherein the A is any one of platinum and palladium, and the B is any one of cobalt and chromium.

4. The spin-orbit torque material according to claim 1, wherein the spin-orbit torque material is an ABO₂ thin film which comprises a single-layered or multi-layered ABO₂ atomic layer; and
wherein each ABO₂ atomic layer comprises an A atomic layer and a BO₂ atomic layer, and the multi-layered ABO₂ atomic layer is formed by A atomic layers and BO₂ atomic layers which are stacked alternately.

5. The spin-orbit torque material according to claim 1, wherein the ABO₂ thin film is a single crystal thin film or an amorphous thin film.

6. The spin-orbit torque material according to claim 1, wherein the thickness of the ABO₂ thin film is 8 nm to 150 nm.

7. A spin-orbit torque device, comprising at least one spin-orbit torque material according to of claim 1.

8. The spin-orbit torque device according to claim 7, comprising a spin-orbit torque generating layer which comprises the spin-orbit torque material.

9. The spin-orbit torque device according to claim 7, wherein the spin-orbit torque device is a storage device, a logic device, or a sensor device.

10. The spin-orbit torque device according to claim 7, wherein the spin-orbit torque generating layer is configured to drive magnetization reversal, perturb magnetic moment, or excite magnetic resonance.

11. Use of a delafossite oxide thin film for providing a spin-orbit torque effect, wherein a chemical formula of the delafossite oxide is ABO₂; and
wherein A and B are different heavy metal atoms, O is an oxygen atom, and a ratio between the numbers of A, B, and O atoms is 1:1:2.

12. The use according to claim 11, wherein the A and B are each independently any one of platinum, palladium, cobalt, chromium, tantalum, tungsten, copper, hafnium, rhenium, iridium, gold, silver, and titanium.

13. The use according to claim 11, wherein the A is any one of platinum and palladium, and the B is any one of cobalt and chromium.

14. The use according to claim 11, wherein the delafossite oxide thin film comprises a single-layered or multi-layered ABO₂ atomic layer; and
wherein each ABO₂ atomic layer comprises an A atomic layer and a BO₂ atomic layer, and the multi-layered ABO₂ atomic layer is formed by A atomic layers and BO₂ atomic layers which are stacked alternately.

15. The use according to claim 11, wherein the use comprises the employment of the delafossite oxide thin film in a spin-orbit torque storage device, a spin-orbit torque logic device, or a spin-orbit torque sensor device to provide a spin-orbit torque effect, and the utilization of the spin-orbit torque effect to drive magnetization reversal, perturb magnetic moment, or excite magnetic resonance.
